(19) United States
(12) Patent Application Publication
(10) Pub. No.: US 2021/0217784 A1
(43) Pub. Date: Jul. 15, 2021

(54) ARRAY SUBSTRATE, METHOD FOR MANUFACTURING ARRAY SUBSTRATE, AND DISPLAY PANEL

(71) Applicant: BOE TECHNOLOGY GROUP CO., LTD., Beijing (CN)

(72) Inventors: Zhengliang Li, Beijing (CN); Jiayu He, Beijing (CN); Hehe Hu, Beijing (CN); Wenlin Zhang, Beijing (CN); Song Liu, Beijing (CN); Xiaochen Ma, Beijing (CN); Nianqi Yao, Beijing (CN); Jie Huang, Beijing (CN)

(73) Assignee: BOE TECHNOLOGY GROUP CO., LTD., Beijing (CN)

(21) Appl. No.: 16/761,335

(22) PCT Filed: Nov. 21, 2019
(86) PCT No.: PCT/CN2019/119932

§ 371 Date: May 4, 2020

(30) Foreign Application Priority Data
Feb. 1, 2019 (CN) 201910103639.5

(51) Int. Cl. H01L 27/144

(52) U.S. Cl. CPC H01L 27/1443; H01L 27/3269

(57) ABSTRACT

An array substrate, a method for manufacturing an array substrate, and a display panel are provided. The array substrate includes: a base substrate; a thin film transistor on the base substrate; and a PIN diode on a side of the thin film transistor away from the base substrate, in a direction running away the base substrate from the thin film transistor, the PIN diode including a first electrical conduction type semiconductor layer and an intrinsic semiconductor layer and a second electrical conduction type semiconductor layer stacked in sequence, wherein a material from which the first electrical conduction type semiconductor layer is made includes one or more of following materials: metal oxide, metal sulfide, metal selenide, metal nitride, metal phosphide, or metal arsenide.

### CROSS-REFERENCE TO RELATED APPLICATION

This application claims the benefit of Chinese Patent Application No. 201910103639.5 filed on Feb. 1, 2019 in China National Intellectual Property Administration, the disclosure of which is incorporated herein by reference in entirety.

### TECHNICAL FIELD

Embodiments of the present disclosure relate to the field of display technology, and in particular, to an array substrate, a method for manufacturing an array substrate, and a display panel.

### BACKGROUND

The OLED display panel has a characteristic of self-luminous, and has many advantages such as wide color gamut, high contrast, ultra-light and ultra-thin compared with a liquid crystal display panel. However, since the OLED display panel needs to operate for a long time under a condition of high contrast and high brightness, the brightness of organic light emitting layers in sub-pixels of the OLED display panel degenerates inconsistently, which leads to uneven light emission of the OLED display panel. Therefore, it is necessary to compensate the brightness of the sub-pixels of the OLED display panel. Currently, the common compensation method includes electrical compensation and optical compensation.

### SUMMARY

According to an aspect of the present disclosure, there is provided an array substrate, comprising: a base substrate; a thin film transistor on the base substrate; and a PIN diode on a side of the thin film transistor away from the base substrate, in a direction running away the base substrate from the thin film transistor, the PIN diode comprising a first electrical conduction type semiconductor layer and an intrinsic semiconductor layer and a second electrical conduction type semiconductor layer stacked in sequence, wherein a material from which the first electrical conduction type semiconductor layer is made comprises one or more of following materials: metal oxide, metal sulfide, metal selenide, metal nitride, metal phosphide, or metal arsenide.

According to some embodiments of the present disclosure, the thin film transistor comprises an active layer, a gate insulating layer, a gate electrode, an interlayer insulating layer, a source electrode and a drain electrode, and the PIN diode is disposed on a side of the drain electrode or the source electrode away from the active layer.

According to some embodiments of the present disclosure, the first electrical conduction type semiconductor layer has a thickness of about 100 Å˜2000 Å; the intrinsic semiconductor layer has a thickness of about 7000 Å˜15000 Å; and the second electrical conduction type semiconductor layer has a thickness of about 20 Å˜500 Å.

According to some embodiments of the present disclosure, the first electrical conduction type semiconductor layer is of n-type electrical conduction, and a material from which the first electrical conduction type semiconductor layer is made is selected from at least one of indium gallium zinc oxide, indium tin zinc oxide, indium tin gallium oxide, indium gallium zinc tin oxide, indium zinc oxide, gallium zinc oxide, zinc oxynitride, aluminum-doped indium zinc oxide, aluminum and neodymium-doped indium zinc oxide, aluminum-doped gallium zinc oxide, or aluminum and neodymium-doped gallium zinc oxide;

wherein the second electrical conduction type semiconductor layer is of p-type electrical conduction, and a material from which the second electrical conduction type semiconductor layer is made is selected from at least one of cuprous oxide, copper aluminum oxide, gallium sulfide, indium sulfide, gallium selenide, zinc nitride, zinc phosphide, gallium phosphide, zinc arsenide, or amorphous silicon.

According to some embodiments of the present disclosure, the first electrical conduction type semiconductor layer is of p-type electrical conduction, and a material from which the first electrical conduction type semiconductor layer is made is selected from at least one of cuprous oxide, copper aluminum oxide, gallium sulfide, indium sulfide, gallium selenide, zinc nitride, zinc phosphide, gallium phosphide, or zinc arsenide;

wherein the second electrical conduction type semiconductor layer is of n-type electrical conduction, and a material from which the second electrical conduction type semiconductor layer is made is selected from at least one of indium gallium zinc oxide, indium tin zinc oxide, indium tin gallium oxide, indium gallium zinc tin oxide, indium zinc oxide, gallium zinc oxide, zinc oxynitride, aluminum-doped indium zinc oxide, aluminum and neodymium-doped indium zinc oxide, aluminum-doped gallium zinc oxide, aluminum and neodymium-doped gallium zinc oxide, or amorphous silicon.

According to some embodiments of the present disclosure, a material from which the intrinsic semiconductor layer is made comprises amorphous silicon.

According to some embodiments of the present disclosure, the interlayer insulating layer comprises a plurality of stacked sub-interlayer insulating layers, and two adjacent sub-interlayer insulating layers are made in different manufacturing processes.

According to some embodiments of the present disclosure, the array substrate further comprises two electrode layers, the two electrode layers are respectively disposed on a side of the first electrical conduction type semiconductor layer away from the intrinsic semiconductor layer and a side of the second electrical conduction type semiconductor layer away from the intrinsic semiconductor layer, and are respectively electrically connected to the first electrical conduction type semiconductor layer and the second electrical conduction type semiconductor layer.

According to some embodiments of the present disclosure, the array substrate further comprises an electrode layer disposed on a side of the second electrical conduction type semiconductor layer away from the intrinsic semiconductor layer and electrically connected to the second electrical conduction type semiconductor layer, and the first electrical conduction type semiconductor layer is in direct contact with and electrically connected to the drain electrode or the electrode source.

According to some embodiments of the present disclosure, the gate insulating layer is disposed on a surface of the active layer away from the base substrate; the gate electrode is disposed on a surface of the gate insulating layer away from the base substrate; the interlayer insulating layer is disposed on the side of the base substrate close to the active layer, and covers the active layer, the gate insulating layer and the gate electrode which are exposed; the source electrode and the drain electrode are disposed on a surface of the interlayer insulating layer away from the base substrate, and the source electrode and the drain electrode are respectively electrically connected to the active layer through first via holes.

According to some embodiments of the present disclosure, the array substrate further comprises:

a light shielding layer disposed on the base substrate; and

a buffer layer disposed on the base substrate and covers the light shielding layer,

wherein the active layer and the interlayer insulating layer are disposed on a surface of the buffer layer away from the light shielding layer.

According to some embodiments of the present disclosure, the array substrate further comprises:

a first insulating layer disposed on a surface of the interlayer insulating layer away from the base substrate and covering the source electrode and the drain electrode;

a hydrogen barrier layer disposed on a surface of the first insulating layer away from the base substrate and electrically connected to the gate electrode through a second via hole;

a first electrode layer electrically connected to the drain electrode or the source electrode through a third via hole;

a second electrode layer disposed on a surface of the second electrical conduction type semiconductor layer away from the base substrate;

a second insulating layer disposed on a surface of the first insulating layer away from the base substrate and covering the hydrogen barrier layer, the first electrode layer, the first electrical conduction type semiconductor layer, the intrinsic semiconductor layer, the second electrical conduction type semiconductor layer, and the second electrode layer which are exposed;

a planarization layer disposed on a surface of the second insulating layer away from the base substrate;

a third electrode layer disposed on a surface of the planarization layer away from the base substrate and electrically connected to the second electrode layer through a fourth via hole; and

a pixel defining layer disposed on a surface of the third electrode layer away from the base substrate,

wherein the first electrical conduction type semiconductor layer is disposed on a surface of the first electrode layer away from the base substrate;

wherein the intrinsic semiconductor layer is disposed on a surface of the first electrical conduction type semiconductor layer away from the base substrate;

wherein the second electrical conduction type semiconductor layer is disposed on a surface of the intrinsic semiconductor layer away from the base substrate.

According to some embodiments of the present disclosure, the array substrate further comprises:

a second electrode layer disposed on a surface of the second electrical conduction type semiconductor layer away from the base substrate;

a second insulating layer disposed on a surface of the interlayer insulating layer away from the base substrate and covering the source electrode, the drain electrode, the first electrical conduction type semiconductor layer, the intrinsic semiconductor layer, the second electrical conduction type semiconductor layer, and the second electrode layer which are exposed;

a planarization layer disposed on a surface of the second insulating layer away from the base substrate;

a third electrode layer disposed on a surface of the planarization layer away from the base substrate and electrically connected to the second electrode layer through a fourth via hole; and

a pixel defining layer disposed on a surface of the third electrode layer away from the base substrate,

wherein the first electrical conduction type semiconductor layer is disposed on a surface of the drain electrode or the source electrode away from the base substrate;

wherein the intrinsic semiconductor layer is disposed on a surface of the first electrical conduction type semiconductor layer away from the base substrate;

wherein the second electrical conduction type semiconductor layer is disposed on a surface of the intrinsic semiconductor layer away from the base substrate.

According to some embodiments of the present disclosure, the hydrogen barrier layer and the first electrode layer are disposed in a same layer.

According to some embodiments of the present disclosure, the first electrical conduction type semiconductor layer is manufactured in a hydrogen-free atmosphere.

According to another aspect of the present disclosure, there is provided a display panel, comprising the array substrate according to any one of the above embodiments.

According to a further aspect of the present disclosure, there is provided a method for manufacturing an array substrate, comprising:

forming a thin film transistor on a base substrate;

forming a first semiconductor layer on a side of the thin film transistor away from the base substrate;

forming an intermediate semiconductor layer on a surface of the first semiconductor layer away from the thin film transistor, the intermediate semiconductor layer covering the first semiconductor layer;

forming a second semiconductor layer on a surface of the intermediate semiconductor layer away from the thin film transistor, the second semiconductor layer covering the intermediate semiconductor layer; and patterning the first semiconductor layer, the intermediate semiconductor layer, and the second semiconductor layer to form a first electrical conduction type semiconductor layer, an intrinsic semiconductor layer and a second electrical conduction type semiconductor layer, which constitute a PIN diode, on a surface of the thin film transistor away from the base substrate,

wherein a material from which the first electrical conduction type semiconductor layer is made comprises one or more of following materials: metal oxide, metal sulfide, metal selenide, metal nitride, metal phosphide, or metal arsenide.

According to some embodiments of the present disclosure, the forming a thin film transistor on a base substrate comprises: forming an active layer, a gate insulating layer, a gate electrode, an interlayer insulating layer, a source electrode and a drain electrode on the base substrate sequentially,

wherein the first semiconductor layer is formed on a side of the drain electrode or the source electrode away from the active layer, and the first semiconductor layer covers the interlayer insulating layer which is exposed.

According to some embodiments of the present disclosure, the forming an interlayer insulating layer comprises:

forming a plurality of stacked sub-interlayer insulating layers sequentially,

wherein two adjacent sub-interlayer insulating layers are formed in different powers and speeds.

According to some embodiments of the present disclosure, the method further comprises:

forming a light shielding layer on the base substrate;

forming a buffer layer on the base substrate, the buffer layer covering the light shielding layer,

wherein the active layer and the interlayer insulating layer are formed on a surface of the buffer layer away from the light shielding layer.

According to some embodiments of the present disclosure, the first electrical conduction type semiconductor layer is manufactured in a hydrogen-free atmosphere.

### BRIEF DESCRIPTION OF THE DRAWINGS

FIG. 1 is a schematic structural view of a thin film transistor according to an embodiment of the present disclosure;

FIG. 2 is a schematic structural view of a thin film transistor according to an embodiment of the present disclosure;

FIG. 3 is a schematic structural view of a thin film transistor according to an embodiment of the present disclosure;

FIG. 4 is a schematic flowchart of a method for manufacturing a thin film transistor according to an embodiment of the present disclosure;

FIG. 5 is a schematic structural view of a thin film transistor during implementing a method for manufacturing the thin film transistor according to an embodiment of the present disclosure;

FIG. 6 is a schematic structural view of a thin film transistor during implementing a method for manufacturing the thin film transistor according to an embodiment of the present disclosure;

FIG. 7 is a schematic structural view of a thin film transistor during implementing a method for manufacturing the thin film transistor according to an embodiment of the present disclosure;

FIG. 8 is a schematic structural view of a thin film transistor during implementing a method for manufacturing the thin film transistor according to an embodiment of the present disclosure;

FIG. 9 is a schematic structural view of a thin film transistor during implementing a method for manufacturing the thin film transistor according to an embodiment of the present disclosure;

FIG. 10 is a schematic structural view of a thin film transistor during implementing a method for manufacturing the thin film transistor according to an embodiment of the present disclosure; and

FIG. 11 is a schematic structural view of a thin film transistor during implementing a method for manufacturing the thin film transistor according to an embodiment of the present disclosure.

### DETAILED DESCRIPTION OF EMBODIMENTS

The embodiments of the present disclosure will be described in detail below. The embodiments described below are exemplary only for explaining the present disclosure, but should not be construed as limiting the present disclosure. If no specific technologies or conditions are indicated in the embodiments, the technologies or conditions described in the literatures in the prior art or the product specifications are applicable.

The common methods for compensating brightness of sub-pixels in the OLED display panel refer to electrical compensation and optical compensation. However, the effect of electrical compensation is limited, and the problem of uneven light emission of the display panel cannot be solved well. For the optical compensation method, a photosensitive sensor (PIN diode) is provided in the sub-pixel to sense intensity of light emission of the OLED and feed back the detected signal to the thin film transistor in the sub-pixel, and the thin film transistor compensates the brightness of the sub-pixel region according to the detected light brightness. Although this method can better solve the problem of uneven light emission of the display panel, there are still some other problems, for example, the TFT characteristics are affected.

Currently, in order to achieve optical compensation for the OLED, the PIN diode includes n(or p)-type doped amorphous silicon, amorphous silicon, p(or n)-type doped amorphous silicon stacked on a surface of a source electrode or drain electrode. Since the gas atmosphere in which various layer structures of the PIN diode are formed by depositing process mainly includes SiH₄ and hydrogen gas, a hydrogen barrier layer is typically provided on a side of the source electrode and drain electrode away from the base substrate in order to prevent the hydrogen from diffusing into an active layer and electrically conducting the active layer when the PIN diode is manufactured. The material of the hydrogen barrier layer is typically the same as the material of the source electrode and drain electrode. For a thin film transistor (TFT) with such a structure, the designer unexpectedly found that the hydrogen barrier layer cannot completely prevent the hydrogen from diffusing into the active layer, that is, to some extent, the active layer is still electrically conducted by the hydrogen, resulting in the active layer being in a state of heavy current and thereby seriously affecting the TFT characteristics. In response to the above problems, the designer proposes to replace the doped amorphous silicon provided on the surface of the source electrode or drain electrode with a first electrical conduction type semiconductor layer which does not contain hydrogen and is manufactured in a hydrogen-free atmosphere, wherein the first electrical conduction type semiconductor layer is formed of metal oxide, metal sulfide, metal selenide, metal nitride, metal phosphide or metal arsenide. The first electrical conduction type semiconductor layer can be used as a barrier layer when an intrinsic semiconductor layer and a second electrical conduction type semiconductor layer are manufactured, to prevent hydrogen from adversely affecting the active layer, to prevent the active layer from being electrically conducted. Thus, it solves the problem of large current in the active layer, and further greatly improves the TFT characteristics.

The embodiments of the present disclosure aim to propose a thin film transistor having advantages of good optical compensation effect, stable TFT characteristics, or simple manufacturing processes.

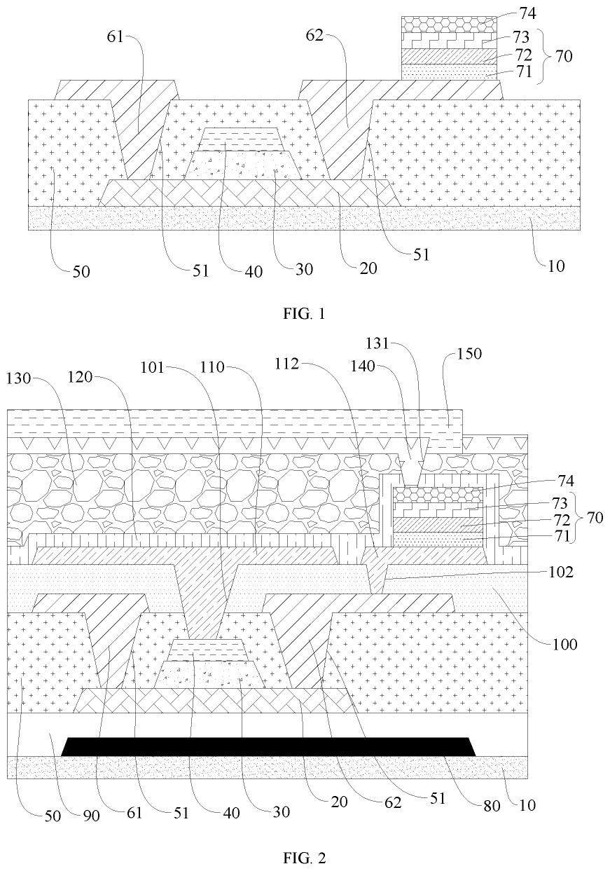

In one aspect of the present disclosure, an embodiment of the present disclosure provides a thin film transistor. Referring to FIG. 1, the thin film transistor includes an active layer 20, a gate insulating layer 30, a gate electrode 40, an interlayer insulating layer 50, a source electrode 61 and a drain electrode 62. According to the embodiment of the present disclosure, a PIN diode 70 is provided on a side of the drain electrode 62 or the source electrode 61 away from the active layer 20 (in the drawings, providing it on a side of the drain electrode 62 is taken as an example). In a direction running away the active layer 20 from the drain electrode 62 or the source electrode 61, the PIN diode 70 includes a first electrical conduction type semiconductor layer 71, an intrinsic semiconductor layer 72, and a second electrical conduction type semiconductor layer 73 which are sequentially stacked. The first electrical conduction type semiconductor layer 71 is formed of metal oxide, metal sulfide, metal selenide, metal nitride, metal phosphide or metal arsenide. In this way, since the first electrical conduction type semiconductor layer formed from metal oxide, metal sulfide, metal selenide, metal nitride, metal phosphide or metal arsenide is disposed on a side of the source electrode or the drain electrode, and the above materials and the manufacturing atmosphere of the first electrical conduction type semiconductor layer do not contain hydrogen, it will not adversely affect the active layer. Moreover, the first electrical conduction type semiconductor layer can be used as a barrier layer when an intrinsic semiconductor layer and a second electrical conduction type semiconductor layer are manufactured, to prevent hydrogen from adversely affecting the active layer, to prevent the active layer from being electrically conducted, thereby improving the characteristics of the thin film transistor.

According to the embodiments of the present disclosure, the structure type of the thin film transistor is not limited, and it can be flexibly designated by those skilled in the art according to actual needs. In the embodiments of the present disclosure, the thin film transistor may be of a top-gate structure, a bottom-gate structure, an etch conductively-resistant type structure, or a back channel etch type structure. Therefore, there are no restrictions on the specific type of thin film transistor. In the following embodiments, the top-gate structure is taken as an example to describe the structure of the thin film transistor in detail.

According to an embodiment of the present disclosure, as shown in FIG. 1, in order to meet the usage requirements of TFT, the active layer 20 is disposed on a surface of the base substrate 10, the gate insulating layer 30 is disposed on a surface of the active layer 20 away from the base substrate 10, the gate electrode 40 is disposed on a surface of the gate insulating layer 30 away from the base substrate 10, the interlayer insulating layer 50 is disposed on the surface of the base substrate 10 and covers the exposed active layer 20, gate insulating layer 30 and gate electrode 40, the source electrode 61 and the drain electrode 62 are disposed on a surface of the interlayer insulating layer 50 away from the base substrate 10 and electrically connected to the active layer 20 through first via holes 51, and the PIN diode 70 is disposed on a surface of the drain electrode 62. In order to realize the optical compensation of the PIN diode, a second electrode layer 74 is further provided on a surface of the PIN diode 70 away from the base substrate 10, and the PIN diode 70 can realize its optical compensation effect by connecting it to the drain electrode 62 and the second electrode layer 74 respectively.

According to the embodiments of the present disclosure, electrodes need to be provided on both sides of the PIN diode to meet their working requirements. In some embodiments of the present disclosure, electrodes may be provided on surfaces of the first electrical conduction type semiconductor layer and the second electrical conduction type semiconductor layer, respectively. In other embodiments of the present disclosure, as shown in FIG. 1, the first electrical conduction type semiconductor layer may be disposed on the surface of the source electrode or drain electrode, so that the source electrode or drain electrode may be used as one electrode of the PIN diode, and then another electrode (i.e., the second electrode layer 74 in FIG. 1) is disposed on a surface of the second electrical conduction type semiconductor layer.

According to the embodiments of the present disclosure, the specific materials for forming the base substrate, the active layer, the gate insulating layer, the gate electrode, the interlayer insulating layer, the source electrode, the drain electrode, and the second electrode layer are not limited, and they can be flexibly designated by those skilled in the art according to actual needs, for example, the specific materials for forming the base substrate include but are not limited to polymers or glass, the materials for forming the active layer include but are not limited to indium gallium zinc oxide, amorphous silicon, polycrystalline silicon, hexathiophene or polythiophene, or the like, the materials for forming the gate insulating layer and the interlayer insulating layer include but are not limited to silicon nitride, silicon oxide, silicon oxynitride or organic insulating materials, the materials for forming the gate electrode are selected from at least one of silver, copper, aluminum, molybdenum, metal alloy or indium tin oxide, the materials for forming the source and drain electrodes are selected from at least one of silver, copper, aluminum, molybdenum, metal alloy or indium tin oxide, the materials for forming the second electrode layer is selected from at least one of silver, copper, aluminum, molybdenum, metal alloy or indium tin oxide.

In the related art, the interlayer insulating layer is generally only used as an insulating layer, and the power and speed set in the entire process of depositing the interlayer insulating layer remain unchanged, but the designer found that the interlayer insulating layer can also prevent hydrogen from diffusing into the active layer to a certain extent, and the interlayer insulating layer obtained through high-power and low-speed deposition has a better effect of blocking hydrogen. However, such a manufacturing process requires a longer time and a higher cost. Since the first electrical conduction type semiconductor layer in the embodiments of the present disclosure can already well block hydrogen from diffusing into the active layer, the interlayer insulating layer may include a plurality of stacked sub-interlayer insulating layers, two adjacent one of which are formed in different powers and speeds, in order to further improve the manufacturing rate. In the method of depositing and forming the interlayer insulating layer, a high-quality and good-performance interlayer insulating layer film (high-quality film) can be produced by high power and low speed, and a relatively poor quality interlayer insulating layer film (low-quality film) can be produced by low power and high speed (it should be noted that the “low-quality film” here does not mean that the quality of the interlayer insulating layer film is very poor, but means that the effect of blocking hydrogen diffusion is relatively poor compared to the high-quality film), thus, it is possible to meet the requirements for both the quality and the formation rate of the film at the same time by adjusting the power and the speed by which various sub-interlayer insulating layers are formed. In this way, the obtained interlayer insulating layer can not only better prevent the diffusion of hydrogen, but also shorten the manufacturing time of the interlayer insulating layer, thereby improving the manufacturing efficiency of the thin film transistor.

According to an embodiment of the present disclosure, the power for preparing the interlayer insulating layer is 100 W˜5 kw and the speed rate for preparing the interlayer insulating layer is 2 Å/s˜100 Å/s. Herein, the high power is 1.2 kw-5 kw (for example, 1.2 kw, 1.4 kw, 1.6 kw, 1.8 kw, 2 kw, 2.3 kw, 2.5 kw, 2.8 kw, 3 kw, 3.3 kw, 3.5 kw, 4 kw, 4.2 kw, 4.5 kw, 4.8 kw, 5 kw), the low power is 100 W˜1.2 kw (for example, 100 W, 300 W, 500 W, 800 W, 1.0 kw, 1.05 kw, 1.1 kw, 1.15 kw), the high speed rate is 15 Å/s˜100 Å/s (for example, 15 Å/s, 20 Å/s, 25 Å/s, 30 Å/s, 40 Å/s, 50 Å/s, 60 Å/s, 70 Å/s, 80 Å/s, 90 Å/s, 100 Å/s), the low speed rate is 2 Å/s˜15 Å/s (for example, 2 Å/s, 4 Å/s, 6 Å/s, 8 Å/s, 10 Å/s, 12 Å/s, 14 Å/s).

In some embodiments of the present disclosure, high-quality films and low-quality films are alternately stacked to form the interlayer insulating layer, that is, a layer of high-quality film, a layer of low-quality film, a layer of high-quality film, a layer of low-quality film, and so on, are stacked.

According to the embodiments of the present disclosure, there are no restrictions on the thickness of the interlayer insulating layer, and it can be flexibly designated by those skilled in the art according to actual needs. In some embodiments of the present disclosure, the thickness of the interlayer insulating layer is about 3000 Å˜9000 Å, for example, 3000 Å, 3500 Å, 4000 Å, 4500 Å, 6000 Å, 6500 Å, 7000 Å, 7500 Å, 8000 Å, 8500 Å or 9000 Å. In this way, the interlayer insulating layer has good usage performance and can well block the diffusion of hydrogen.

In the embodiments of the present disclosure, when a numerical value is limited by “about”, its range refers to a range of the defined numerical value ±10%.

According to the embodiments of the present disclosure, the PIN diode realizes the optical compensation based on the following principle: the light illuminates the PIN diode, excites carrier electrons and holes of the first electrical conduction type semiconductor layer and the second electrical conduction type semiconductor layer; the electrons and the holes recombine in the intrinsic semiconductor layer to generate photo-generated carriers, and as the intensity of light increases, the current generated by the carriers increases, thus the intensity of light can be accurately determined according to the magnitude of current; the applied voltage may be changed according to the magnitude of current to achieve the effect of controlling the intensity of light and thereby realize the compensation function.

According to an embodiment of the present disclosure, in order to achieve the above optical compensation function, the first electrical conduction type semiconductor layer is of n-type electrical conduction, and a material for forming the first electrical conduction type semiconductor layer is selected from at least one of indium gallium zinc oxide (IGZO), indium tin zinc oxide (ITZO), indium tin gallium oxide (ITGO), indium gallium zinc tin oxide (IGZTO), indium zinc oxide (IZO), gallium zinc oxide (GZO), zinc oxynitride (ZnON), aluminum-doped indium zinc oxide (Al—IZO), aluminum and neodymium-doped indium zinc oxide (AlNd—IZO), aluminum-doped gallium zinc oxide (Al-GZO), or aluminum and neodymium-doped gallium zinc oxide (AlNd-GZO); the second electrical conduction type semiconductor layer is of p-type electrical conduction, and a material for forming the second electrical conduction type semiconductor layer is selected from at least one of cuprous oxide (Cu₂O), copper aluminum oxide (CuAl₂O), gallium sulfide (GaS), indium sulfide (InS), gallium selenide (GaSe), zinc nitride (ZnN), zinc phosphide (ZnP), gallium phosphide (GaP), zinc arsenide (ZnAs) or amorphous silicon. Therefore, in addition to the optical compensation function effectively realized by the PIN diode, the materials for forming the first electrical conduction type semiconductor layer have a good function of blocking hydrogen diffusion, thereby improving the display effect of the display panel using the thin film transistor. Moreover, when the second electrical conduction type semiconductor layer adopts a material other than the above-mentioned amorphous silicon, neither the material itself nor the manufacturing atmosphere contains hydrogen, therefore the risk of the active layer being electrically conducted can be further reduced.

According to another embodiment of the present disclosure, the first electrical conduction type semiconductor layer is of p-type electrical conduction, and a material for forming the first electrical conduction type semiconductor layer is selected from at least one of cuprous oxide (Cu₂O), copper aluminum oxide (CuAl₂O), Gallium sulfide (GaS), indium sulfide (InS), gallium selenide (GaSe), zinc nitride (ZnN), zinc phosphide (ZnP), gallium phosphide (GaP), or zinc arsenide (ZnAs); the second electrical conduction type semiconductor layer is of n-type electrical conduction, and a material for forming the second electrical conduction type semiconductor layer is selected from at least one of indium gallium zinc oxide (IGZO), indium tin zinc oxide (ITZO), indium tin gallium oxide (ITGO), indium gallium zinc tin oxide (IGZTO), indium zinc oxide (IZO), gallium zinc oxide (GZO), zinc oxynitride (ZnON), aluminum-doped indium zinc oxide (Al—IZO), aluminum and neodymium-doped indium zinc oxide (AlNd—IZO), aluminum-doped gallium zinc oxide (Al-GZO), aluminum and neodymium-doped gallium zinc oxide (AlNd-GZO), or amorphous silicon. Therefore, in addition to the optical compensation function effectively realized by the PIN diode, the materials for forming the first electrical conduction type semiconductor layer have a good function of blocking hydrogen diffusion, thereby improving the display effect of the display panel using the thin film transistor. Moreover, when the second electrical conduction type semiconductor layer adopts a material other than the above-mentioned amorphous silicon, neither the material itself nor the manufacturing atmosphere contains hydrogen, therefore the risk of the active layer being electrically conducted can be further reduced.

According to an embodiment of the present disclosure, in order to improve the optical compensation effect of the PIN diode, the material for forming the intrinsic semiconductor layer includes amorphous silicon. Thereby, the optical compensation effect of the PIN diode is better.

According to an embodiment of the present disclosure, the thickness of the first electrical conduction type semiconductor layer is 100 Å˜2000 Å, for example, 100 Å, 300 Å, 500 Å, 700 Å, 900 Å, 1000 Å, 1200 Å, 1400 Å, 1600 Å, 1800 Å or 2000 Å. In this case, the first electrical conduction type semiconductor layer has a better performance, the resistance thereof will not be too large, without affecting the magnitude of the photocurrent. If the thickness is too small, the first electrical conduction type semiconductor layer cannot form a continuous film; if the thickness is too large, the resistance will increase, which will easily cause the photocurrent to drop. The thickness of the intrinsic semiconductor layer is 7000 Å˜15000 Å, for example, 7000 Å, 8000 Å, 9000 Å, 10000 Å, 11000 Å, 12000 Å, 13000 Å, 14000 Å, 15000 Å. In this case, an intrinsic semiconductor layer with a uniform thickness can be formed, and the usage performance is better. The thickness of the second electrical conduction type semiconductor layer is 20 Å ˜500 Å, for example, 20 Å, 40 Å, 70 Å, 100 Å, 150 Å, 200 Å, 300 Å, 350 Å, 400 Å, 450 Å or 500 Å. In this case, a second electrical conduction type semiconductor layer with a uniform thickness can be formed, and the usage performance is better.

Some structures of the thin film transistor will be described in detail below according to some specific embodiments of the present disclosure.

In some specific embodiments of the present disclosure, referring to FIG. 2, the thin film transistor includes: a base substrate 10; a light shielding layer 80 disposed on an upper surface of the base substrate 10; a buffer layer 90 disposed on the upper surface of the base substrate 10 and covering the light shielding layer 80; an active layer 20 disposed on a surface of the buffer layer 90 away from the light shielding layer 80; a gate insulating layer 30 disposed on a surface of the active layer 20 away from the base substrate 10; a gate electrode 40 disposed on a surface of the gate insulating layer 30 away from the base substrate 10; an interlayer insulating layer 50 disposed on a surface of the buffer layer 90 away from the base substrate 10 and covering the exposed active layer 20, gate insulating layer 30 and gate electrode 40; a source electrode 61 and a drain electrode 62 disposed on a surface of the interlayer insulating layer 50 away from the base substrate 10 and electrically connected to the active layer 20 through first via hole 51 respectively; a first insulating layer 100 disposed on the surface of the interlayer insulating layer 50 away from the base substrate 10 and covering the source electrode 61 and the drain electrode 62; a hydrogen barrier layer 110 disposed on a surface of the first insulating layer 100 away from the base substrate and electrically connected to the gate electrode through a second via hole 101; a first electrode layer 112 electrically connected to the drain electrode 62 or the source electrode 61 through a third via hole 102 (in the manufacturing process, the hydrogen barrier layer 110 and the first electrode layer 112 may be formed by the same patterning process so that the two are in the same layer); a first electrical conduction type semiconductor layer 71 disposed on a surface of the first electrode layer 112 away from the base substrate 10; an intrinsic semiconductor layer 72 disposed on a surface of the first electrical conduction type semiconductor layer 71 away from the base substrate; a second electrical conduction type semiconductor layer 73 disposed on a surface of the intrinsic semiconductor layer 72 away from the base substrate 10; a second electrode layer 74 disposed on a surface of the second electrical conduction type semiconductor layer 73 away from the base substrate 10; a second insulating layer 120 disposed on a surface of the first insulating layer 100 away from the base substrate 10 and covering the exposed hydrogen barrier layer 110, first electrode layer 112, first electrical conduction type semiconductor layer 71, intrinsic semiconductor layer 72, second electrical conduction type semiconductor layer 73 and second electrode layer 74; a planarization layer 130 disposed on a surface of the second insulating layer 120 away from the base substrate 10; a third electrode layer 140 disposed on a surface of the planarization layer 130 away from the base substrate 10 and electrically connected to the second electrode layer 74 through a fourth via hole 131; and a pixel defining layer 150 disposed on a surface of the third electrode layer 140 away from the base substrate 10. In the thin film transistor with such a structure, the hydrogen barrier layer, the first electrical conduction type semiconductor layer, and the interlayer insulating layer can all be used to block the diffusion of hydrogen, to better prevent the active layer from being electrically conducted, thereby solving the problem of large current in the active layer.

Herein, the arrangement of the hydrogen barrier layer 110 and the first electrode layer 112 in the same layer is not limited to that the two are at the same vertical height or have the same thickness. If the two are formed of the same material by the same patterning process, then they are considered to be arranged in the same layer.

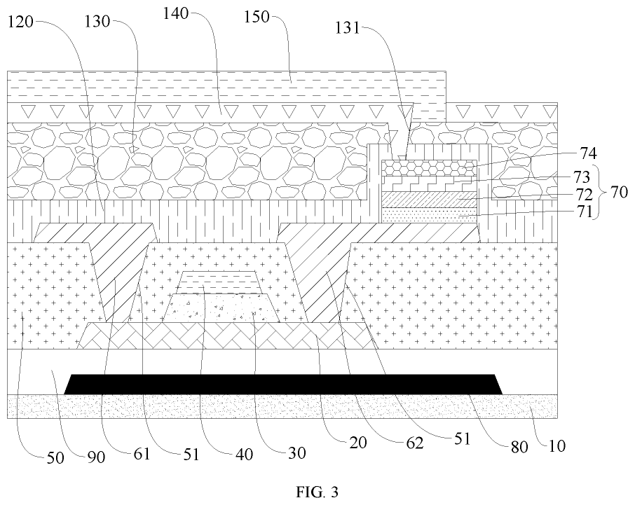

In some other specific embodiments of the present disclosure, referring to FIG. 3, the thin film transistor includes: a base substrate 10; a light shielding layer 80 disposed on an upper surface of the base substrate 10; a buffer layer 90 disposed on the upper surface of the base substrate 10 and covering the light shielding layer 80; an active layer 20 disposed on a surface of the buffer layer 90 away from the light shielding layer 80; a gate insulating layer 30 disposed on a surface of the active layer 20 away from the base substrate 10; a gate electrode 40 disposed on a surface of the gate insulating layer 30 away from the base substrate 10; an interlayer insulating layer 50 disposed on a surface of the buffer layer 90 away from the base substrate 10 and covering the exposed active layer 20, gate insulating layer 30 and gate electrode 40; a source electrode 61 and a drain electrode 62 disposed on a surface of the interlayer insulating layer 50 away from the base substrate 10 and electrically connected to the active layer 20 through first via hole 51 respectively; the first electrical conduction type semiconductor layer 71 disposed on a surface of the drain electrode 62 or the source electrode 61 away from the base substrate 10 (in the drawing, the surface of the drain electrode away from the base substrate is taken as an example); an intrinsic semiconductor layer 72 disposed on a surface of the first electrical conduction type semiconductor layer 71 away from the base substrate 10; a second electrical conduction type semiconductor layer 73 disposed on a surface of the intrinsic semiconductor layer 72 away from the base substrate 10; a second electrode layer 74 disposed on a surface of the second electrical conduction type semiconductor layer 73 away from the base substrate 10; a second insulating layer 120 disposed on the surface of the interlayer insulating layer 50 away from the base substrate 10 and covering the exposed source electrode 61, drain electrode 62, first electrical conduction type semiconductor layer 71, intrinsic semiconductor layer 72, second electrical conduction type semiconductor layer 73, and second electrode layer 74; a planarization layer 130 disposed on a surface of the second insulating layer 120 away from the base substrate 10; a third electrode layer 140 disposed on a surface of the planarization layer 130 away from the base substrate 10 and electrically connected to the second electrode layer 74 through a fourth via hole 131; and a pixel defining layer 150 disposed on a surface of the third electrode layer 140 away from the base substrate 10. Thereby, on the premise of protecting the active layer from being electrically conducted, in order to simplify the processes, the thin film transistor of the above structure is not provided with a hydrogen barrier layer and a first insulating layer, a better blocking effect may be maintained through the first electrical conduction type semiconductor layer and the interlayer insulating layer, that is, the problem of the active layer being electrically conducted can still be solved, and the process flow may be shortened in the manufacturing process and the number of masks may be reduced.

According to the embodiments of the present disclosure, there are no special requirements on the materials for forming the second electrode layer, the third electrode layer, the first insulating layer, the second insulating layer, the planarization layer, the hydrogen barrier layer, and the pixel defining layer, and they may be flexibly designated by those skilled in the art according to actual needs. In some embodiments of the present disclosure, the materials for forming the second electrode layer and the third electrode layer include but are not limited to indium tin oxide (ITO); the materials for forming the first insulating layer, the second insulating layer, the planarization layer and the pixel defining layer are selected from silicon nitride, silicon oxide, silicon oxynitride, organic insulating materials, or the like; the materials for forming the hydrogen barrier layer and the first electrode layer may be selected from the material for manufacturing the source electrode and the drain electrode. As a result, the materials are widely available, the cost is low, and the usage performance of the above structures is better.

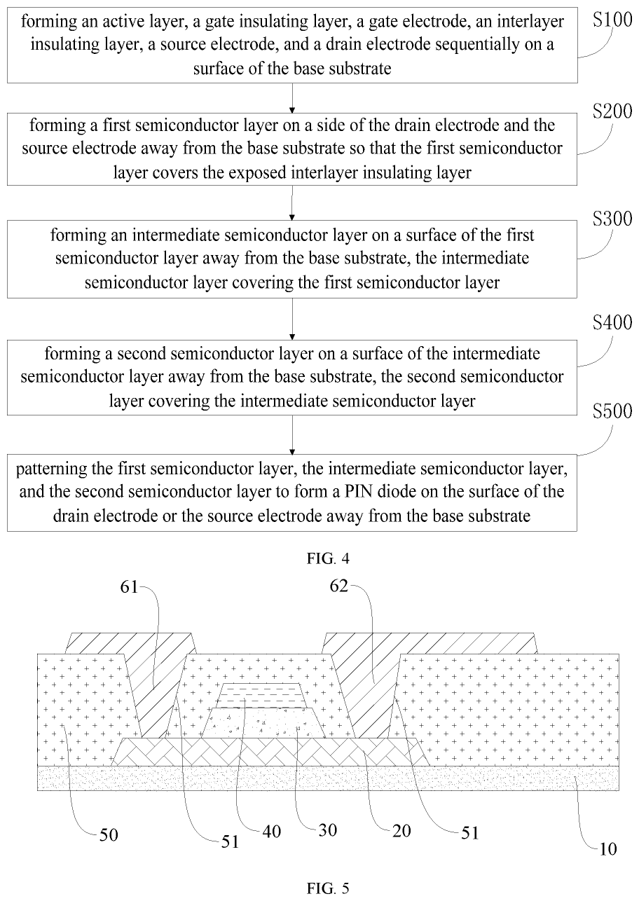

In another aspect of the present disclosure, an embodiment of the present disclosure provides a method for manufacturing the aforementioned thin film transistor. According to the embodiment of the present disclosure, referring to FIG. 4, the above method includes:

S100: forming an active layer 20, a gate insulating layer 30, a gate electrode 40, an interlayer insulating layer 50, a source electrode 61, and a drain electrode 62 sequentially on a surface of the base substrate 10, referring to FIG. 5 for a schematic structural view.

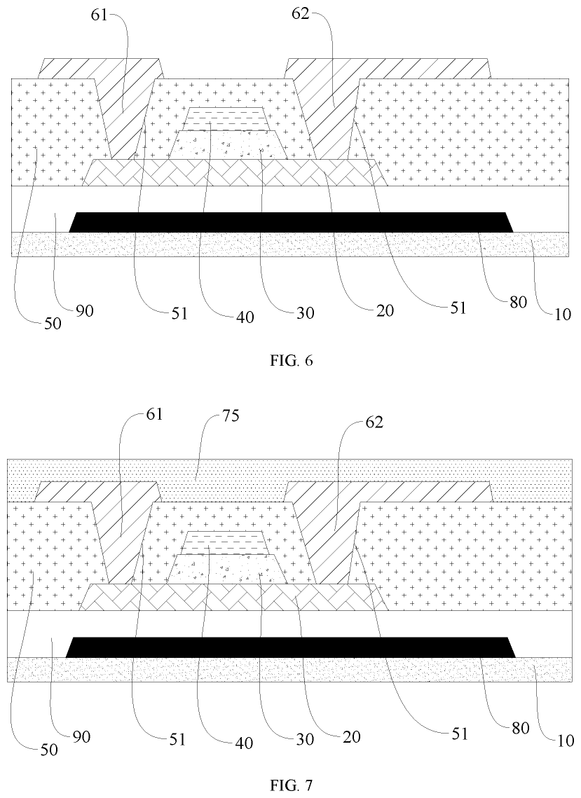

According to the embodiment of the present disclosure, before forming the active layer, it may further include a step of forming a light shielding layer 80 and a buffer layer 90, referring to FIG. 6 for a schematic structural view. The method for forming the above-mentioned light shielding layer 80, buffer layer 90, and active layer 20, gate insulating layer 30, gate electrode 40, interlayer insulating layer 50, source electrode 61 and drain electrode 62 is not limited, and they may be flexibly manufactured by those skilled in the art by using conventional technical means according to actual needs. The forming steps and methods of the above structures will be described in detail below according to some specific embodiments of the present disclosure.

A light shielding layer film is deposited on a surface of the base substrate 10, and then the light shielding layer film is patterned through a patterning process (including steps of forming photoresist, etching, stripping, etc.) to obtain a light shielding layer 80; a buffer layer 90 is deposited on the surface of the base substrate 10 so that it covers the light shielding layer 80; an active layer film is deposited and formed on a surface of the buffer layer 90 away from the base substrate, and then the active layer film is patterned through a patterning process to obtain the active layer 20; a gate insulating layer 30 is deposited and formed on a surface of the active layer 20 away from the base substrate, wherein the gate insulating layer may be a whole layer, or a patterned structure obtained by a patterning process; a gate electrode film is deposited and formed on a surface of the gate insulating layer 30 away from the base substrate, the gate electrode film covers the exposed active layer and base substrate, and then the gate electrode film is patterned by a patterning process to obtain the gate electrode 40; an interlayer insulating layer 50 is deposited and formed on the surface of the base substrate, the interlayer insulating layer 50 covers the exposed active layer 20, gate insulating layer 30 and gate electrode 40; first via holes 51 are formed in the interlayer insulating layer by etching, the first via holes 51 expose parts of the active layer 20; a source/drain electrode film is deposited on a surface of the interlay insulating layer 50 away from the base substrate, and then the source/drain electrode film is patterned through a patterning process to obtain a source electrode 61 and a drain electrode 62, and the source electrode 61 and the drain electrode 62 are electrically connected to the active layer 20 through the first via holes 51.

According to the embodiments of the present disclosure, as described above, the provision of the interlayer insulating layer can also prevent hydrogen from diffusing into the active layer to a certain extent. On this basis, in order to increase the manufacturing rate, the step of forming the interlayer insulating layer includes: forming a plurality of stacked sub-interlayer insulating layers in sequence, wherein two adjacent sub-interlayer insulating layers are formed in different powers and speeds. In the method of depositing and forming the interlayer insulating layer, a high-quality and good-performance interlayer insulating layer film can be produced by high power and low speed, and a relatively poor quality interlayer insulating layer film can be rapidly produced by low power and high speed, thus, it is possible to meet the requirements for both the quality and the formation rate of the film at the same time by adjusting the power and the speed by which various sub-interlayer insulating layers are formed. In this way, the obtained interlayer insulating layer can not only better prevent the diffusion of hydrogen, but also shorten the manufacturing time of the interlayer insulating layer, thereby improving the manufacturing efficiency of the thin film transistor.

According to the embodiments of the present disclosure, there are no restrictive requirements on the specific deposition method described above, either a physical vapor deposition (for example, magnetron sputtering) or a chemical vapor deposition (for example, plasma-enhanced chemical vapor deposition) may be selected, and therefore it will not be limited herein.

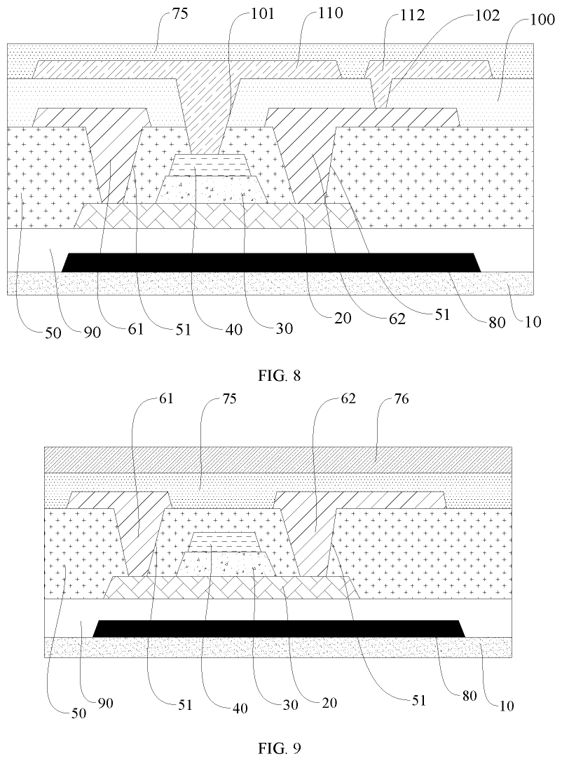

S200: forming a first semiconductor layer 75 on a side of the drain electrode 62 and the source electrode 61 away from the base substrate 10 so that the first semiconductor layer 75 covers the exposed interlayer insulating layer 50, referring to FIGS. 7 and 8 for schematic structures views.

According to the embodiments of the present disclosure, it is possible to determine whether to provide a hydrogen barrier layer on the side of the source electrode and drain electrode away from the base substrate before forming the first semiconductor layer according to actual needs. The above two cases will be described in detail below according to some specific embodiments of the present disclosure.

In some embodiments of the present disclosure, referring to FIG. 7, the hydrogen barrier layer is not provided, that is, the first semiconductor layer 75 is directly provided on the surface of the source electrode 61 and the drain electrode 62. Although there is no hydrogen barrier layer provided, the first semiconductor layer 75 can still well block the diffusion of hydrogen in the subsequent processes, and well protect the active layer from being electrically conducted, that is, it can still solve the problem of large current in the active layer. Moreover, compared with the scheme of providing a hydrogen barrier layer, this method can reduce two photolithography processes, reduce the number of masks, thereby reducing the manufacturing process flow of the thin film transistor and improving the manufacturing efficiency.

In other embodiments of the present disclosure, referring to FIG. 8, before forming the first semiconductor layer 75, the method may further include: depositing and forming a first insulating layer 100 on a surface of the interlayer insulating layer 50 away from the base substrate 10, the first insulating layer 100 covering the source electrode 61 and the drain electrode 62; etching the first insulating layer 100 to form a second via hole 101 and a third via hole 102, the second via hole 101 and the third via hole 102 respectively exposing a part of the surface of the gate electrode 40 and a part of the surface of the drain electrode 62; depositing and forming a hydrogen barrier layer 110 and a first electrode layer 112 on a surface of the first insulating layer 100 away from the base substrate, the hydrogen barrier layer 110 being electrically connected to the gate electrode through the second via hole 101, and the first electrode layer 112 being electrically connected to the drain electrode 62 or the source electrode 61 through the third via hole 102 (in FIG. 8, the drain electrode is taken as an example); then depositing and forming the first semiconductor layer 75 on the surface of the hydrogen barrier layer 110 and the first electrode layer 112, the first semiconductor layer 75 covering the exposed surface of the first insulating layer 100. Thus, the arrangement of the first insulating layer 100 and the hydrogen barrier layer 110 may further prevent the diffusion of hydrogen and protect the active layer from being electrically conducted.

According to the embodiments of the present disclosure, the specific method for forming the first semiconductor layer 75 is also not limited, either a physical vapor deposition (for example, magnetron sputtering) or a chemical vapor deposition (for example, plasma-enhanced chemical vapor deposition) may be selected, and therefore it will not be limited herein.

According to an embodiment of the present disclosure, the material for forming the first semiconductor layer is selected from at least one of n-type doped indium gallium zinc oxide (IGZO), indium tin zinc oxide (ITZO), indium tin gallium oxide (ITGO), indium gallium zinc Tin oxide (IGZTO), indium zinc oxide (IZO), gallium zinc oxide (GZO), zinc oxynitride (ZnON), aluminum-doped indium zinc oxide (Al—IZO), aluminum and neodymium-doped indium zinc oxide (AlNd—IZO), aluminum-doped gallium zinc oxide (Al-GZO), or aluminum and neodymium-doped gallium zinc oxide (AlNd-GZO), or is selected from at least one of p-type doped cuprous oxide (Cu₂O), copper aluminum oxide (CuAl₂O), gallium sulfide (GaS), indium sulfide (InS), gallium selenide (GaSe), zinc nitride (ZnN), zinc phosphide (ZnP), gallium phosphide (GaP) or zinc arsenide (ZnAs). Since none of the above-mentioned materials themselves contain hydrogen and the manufacturing atmosphere does not contain hydrogen, the arrangement of the first semiconductor layer does not adversely affect the active layer, that is, the active layer will not be electrically conducted.

S300: forming an intermediate semiconductor layer 76 on a surface of the first semiconductor layer 75 away from the base substrate, the intermediate semiconductor layer 76 covering the first semiconductor layer 75, referring to FIG. 9 for a schematic structural view (in FIG. 9, no provision of hydrogen barrier layer is taken as an example).

According to the embodiments of the present disclosure, the specific method for forming the intermediate semiconductor layer 76 is also not limited, either a physical vapor deposition (for example, magnetron sputtering) or a chemical vapor deposition (for example, plasma-enhanced chemical vapor deposition) may be selected, and therefore it will not be limited herein.

According to the embodiments of the present disclosure, due to the arrangement of the interlayer insulating layer and the first semiconductor layer, even if the intermediate semiconductor layer is formed from amorphous silicon with a large amount of hydrogen in a hydrogen atmosphere and the intermediate semiconductor layer is deposited for a long time when preparing the intermediate semiconductor layer, the hydrogen will not diffuse into the active layer under the blocking of the interlayer insulating layer and the first semiconductor layer.

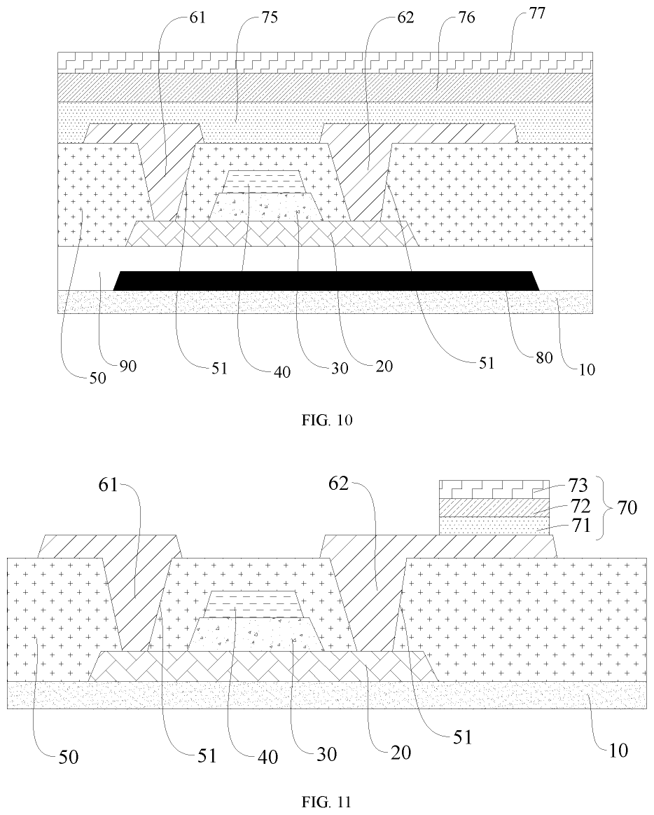

S400: forming a second semiconductor layer 77 on a surface of the intermediate semiconductor layer 76 away from the base substrate 10, the second semiconductor layer 77 covering the intermediate semiconductor layer 76, referring to FIG. 10 for a schematic structural view (in FIG. 10, no provision of hydrogen barrier layer is taken as an example).

According to the embodiments of the present disclosure, the specific method for forming the second semiconductor layer 77 is also not limited, either a physical vapor deposition (for example, magnetron sputtering) or a chemical vapor deposition (for example, plasma-enhanced chemical vapor deposition) may be selected, and therefore it will not be limited herein.

According to the embodiments of the present disclosure, due to the arrangement of the first semiconductor layer, when preparing the second semiconductor layer, regardless of whether the material used contains hydrogen or not, whether the deposition atmosphere contains hydrogen or not, or whether the deposition is implemented for a long time, the hydrogen will not diffuse into the active layer under the blocking of the interlayer insulating layer and the first semiconductor layer.

S500: patterning the first semiconductor layer 75, the intermediate semiconductor layer 76, and the second semiconductor layer 77 to form a PIN diode 70 on the surface of the drain electrode 62 or the source electrode 61 away from the base substrate, referring to FIG. 11 for a schematic structural view (in FIG. 11, no provision of hydrogen barrier layer is taken as an example).

According to the embodiments of the present disclosure, the specific methods and steps of patterning are not limited, and they may be flexibly determined by those skilled in the art according to the specific materials of the intermediate semiconductor layer and the second semiconductor layer. In some embodiments of the present disclosure, the intermediate semiconductor layer and the second semiconductor layer are both formed of amorphous silicon, which is different from that of the first semiconductor material. Therefore, it is possible to first pattern the intermediate semiconductor layer and the second semiconductor layer by dry etching to form the intrinsic semiconductor layer and the second electrical conduction type semiconductor layer, and then pattern the first semiconductor layer by wet etching to form the first electrical conduction type semiconductor layer, thereby obtaining the PIN diode. In other embodiments of the present disclosure, if the intermediate semiconductor layer is formed of amorphous silicon and the second semiconductor layer is formed of metal oxide, metal sulfide, metal selenide, metal nitride, metal phosphide or metal arsenide, then the second semiconductor layer, the intermediate semiconductor layer, and the first semiconductor layer may be respectively patterned by wet etching, dry etching, and wet etching, to obtain the PIN diode.

According to an embodiment of the present disclosure, in order to further improve the structure of the thin film transistor, it further includes: forming a second electrode layer 74 on a surface of the second electrical conduction type semiconductor layer 73 away from the base substrate 10 through a patterning process; depositing and forming a second insulating layer 120 on a surface of the first insulating layer 100 or the interlayer insulating layer 50 away from the base substrate 10, the second insulating layer 120 covering the exposed source electrode 61, drain electrode 62, first electrical conduction type semiconductor layer 71, intrinsic semiconductor layer 72, second electrical conduction type semiconductor layer 73 and the second electrode layer 74; depositing and forming a planarization layer 130 on a surface of the second insulating layer 120 away from the base substrate; forming a fourth via hole 131 in a surface of the planarization layer 130 by etching, the fourth via hole 131 penetrating the second insulating layer 120 and exposing a part of the surface of the second electrode layer 74; forming a third electrode layer 140 on the surface of the planarization layer 130 away from the base substrate by steps such as deposition, etching and stripping; forming a pixel defining layer 150 on a surface of the third electrode layer 140 away from the base substrate 10 by steps such as deposition, etching, and stripping, referring to FIG. 2 and FIG. 3 for schematic structural views.

According to the embodiments of the present disclosure, since the metal oxide, metal sulfide, metal selenide, metal nitride, metal phosphide or metal arsenide itself and the manufacturing atmosphere thereof do not contain hydrogen, the provision and manufacture of the first electrical conduction type semiconductor layer will not electrically conduct the active layer. Moreover, the first electrical conduction type semiconductor layer is first formed on a first surface of the source electrode or the drain electrode, therefore it can be used to prevent the hydrogen from diffusing into the active layer when manufacturing the intrinsic semiconductor layer and the second electrical conduction type semiconductor layer (it can be used as a barrier layer to prevent the hydrogen from negatively affecting the active layer when manufacturing the intrinsic semiconductor layer and the second electrical conduction type semiconductor layer), to prevent the active layer from being electrically conducted, and thereby to improve the characteristics of the thin film transistors. In addition, the above-mentioned manufacturing process is well-developed, easy to operate, and easy to realize industrial production.

It will be appreciated by those skilled in the art that the forming materials of the above structures are the same as those described above, and therefore they will not be described again.

In yet another aspect of the present disclosure, an embodiment of the present disclosure provides a display panel. According to the embodiment of the present disclosure, the display panel includes the aforementioned thin film transistor. Thus, the characteristics of the thin film transistor in the display panel are good, and the display effect of the display panel is better. It will be appreciated by those skilled in the art that the display panel has all the features and advantages of the thin film transistor described above.

Of course, it will be appreciated by those skilled in the art that, in addition to the aforementioned thin film transistor, the above display panel also includes the structures or components necessary for the conventional display panel, for example, a hole transport layer, a light emitting layer, an electron transport layer, and an encapsulation film, and the like.

In still another aspect of the present disclosure, an embodiment of the present disclosure provides a display device. According to the embodiment of the present disclosure, the display device includes the aforementioned display panel or thin film transistor. Thus, the display device has better display effect and stable performance. It will be appreciated by those skilled in the art that the display device has all the features and advantages of the thin film transistor or the display panel described above, and therefore they will not be described again.

Of course, it will be appreciated by those skilled in the art that, in addition to the aforementioned thin film transistor or display panel, the above display device also includes the structure or components necessary for the conventional display device. Taking a mobile phone as an example, in addition to the aforementioned thin film transistor or display panel, the display device also includes a glass cover, a housing, a CPU processor, a fingerprint module, an audio module, a touch module and other structures or components.

In the description of this specification, the description with reference to the terms “one embodiment”, “some embodiments”, “example”, “specific example”, or “some examples” means a specific feature, structure, material or characteristic described in conjunction with the embodiment(s) or example(s) may be included in at least one embodiment or example of the present disclosure. In this specification, the schematic expression of the above terms does not necessarily refer to the same embodiment or example. Moreover, the specific feature, structure, material, or characteristic described may be combined in any one or more embodiments or examples in any suitable manner. In addition, without conflicting with each other, the different embodiments or examples and the features of the different embodiments or examples described in this specification may be combined or united by those skilled in the art.

Although the embodiments of the present disclosure have been shown and described above, it should be understood that the above-mentioned embodiments are exemplary and should not be construed as limiting the present disclosure. Changes, modifications, replacements and variations may be made to the above embodiments by those skilled in the art within the scope of the present disclosure.

1. An array substrate, comprising:
a base substrate;
a thin film transistor on the base substrate; and
a PIN diode on a side of the thin film transistor away from the base substrate, in a direction running away the base substrate from the thin film transistor, the PIN diode comprising a first electrical conduction type semiconductor layer and an intrinsic semiconductor layer and a second electrical conduction type semiconductor layer stacked in sequence,
wherein a material from which the first electrical conduction type semiconductor layer is made comprises one or more of following materials: metal oxide, metal sulfide, metal selenide, metal nitride, metal phosphide, or metal arsenide.

2. The array substrate according to claim 1, wherein the thin film transistor comprises an active layer, a gate insulating layer, a gate electrode, an interlayer insulating layer, a source electrode and a drain electrode, and the PIN diode is disposed on a side of the drain electrode or the source electrode away from the active layer.

3. The array substrate according to claim 1, wherein the first electrical conduction type semiconductor layer has a thickness of about 100 Å ˜2000 Å; the intrinsic semiconductor layer has a thickness of about 7000 Å ˜15000 Å; and the second electrical conduction type semiconductor layer has a thickness of about 20 Å ˜500 Å.

4. The array substrate according to claim 1, wherein the first electrical conduction type semiconductor layer is of n-type electrical conduction, and a material from which the first electrical conduction type semiconductor layer is made is selected from at least one of indium gallium zinc oxide, indium tin zinc oxide, indium tin gallium oxide, indium gallium zinc tin oxide, indium zinc oxide, gallium zinc oxide, zinc oxynitride, aluminum-doped indium zinc oxide, aluminum and neodymium-doped indium zinc oxide, aluminum-doped gallium zinc oxide, or aluminum and neodymium-doped gallium zinc oxide;
wherein the second electrical conduction type semiconductor layer is of p-type electrical conduction, and a material from which the second electrical conduction type semiconductor layer is made is selected from at least one of cuprous oxide, copper aluminum oxide, gallium sulfide, indium sulfide, gallium selenide, zinc nitride, zinc phosphide, gallium phosphide, zinc arsenide, or amorphous silicon.

5. The array substrate according to claim 1, wherein the first electrical conduction type semiconductor layer is of p-type electrical conduction, and a material from which the first electrical conduction type semiconductor layer is made is selected from at least one of cuprous oxide, copper aluminum oxide, gallium sulfide, indium sulfide, gallium selenide, zinc nitride, zinc phosphide, gallium phosphide, or zinc arsenide;
wherein the second electrical conduction type semiconductor layer is of n-type electrical conduction, and a material from which the second electrical conduction type semiconductor layer is made is selected from at least one of indium gallium zinc oxide, indium tin zinc oxide, indium tin gallium oxide, indium gallium zinc tin oxide, indium zinc oxide, gallium zinc oxide, zinc oxynitride, aluminum-doped indium zinc oxide, aluminum and neodymium-doped indium zinc oxide, aluminum-doped gallium zinc oxide, aluminum and neodymium-doped gallium zinc oxide, or amorphous silicon.

6. The array substrate according to claim 1, wherein a material from which the intrinsic semiconductor layer is made comprises amorphous silicon.

7. The array substrate according to claim 2, wherein the interlayer insulating layer comprises a plurality of stacked sub-interlayer insulating layers, and two adjacent sub-interlayer insulating layers are made in different manufacturing processes.

8. The array substrate according to claim 2, wherein the array substrate further comprises two electrode layers, the two electrode layers are respectively disposed on a side of the first electrical conduction type semiconductor layer away from the intrinsic semiconductor layer and a side of the second electrical conduction type semiconductor layer away from the intrinsic semiconductor layer, and are respectively electrically connected to the first electrical conduction type semiconductor layer and the second electrical conduction type semiconductor layer.

9. The array substrate according to claim 2, wherein the array substrate further comprises an electrode layer disposed on a side of the second electrical conduction type semiconductor layer away from the intrinsic semiconductor layer and electrically connected to the second electrical conduction type semiconductor layer, and the first electrical conduction type semiconductor layer is in direct contact with and electrically connected to the drain electrode or the electrode source.

10. The array substrate according to claim 2, wherein the gate insulating layer is disposed on a surface of the active layer away from the base substrate; the gate electrode is disposed on a surface of the gate insulating layer away from the base substrate; the interlayer insulating layer is disposed on the side of the base substrate close to the active layer, and covers the active layer, the gate insulating layer and the gate electrode which are exposed; the source electrode and the drain electrode are disposed on a surface of the interlayer insulating layer away from the base substrate, and the source electrode and the drain electrode are respectively electrically connected to the active layer through first via holes.

11. The array substrate according to claim 10, wherein the array substrate further comprises:
a light shielding layer disposed on the base substrate; and
a buffer layer disposed on the base substrate and covers the light shielding layer,
wherein the active layer and the interlayer insulating layer are disposed on a surface of the buffer layer away from the light shielding layer.

12. The array substrate according to claim 10, further comprising:
a first insulating layer disposed on a surface of the interlayer insulating layer away from the base substrate and covering the source electrode and the drain electrode;
a hydrogen barrier layer disposed on a surface of the first insulating layer away from the base substrate and electrically connected to the gate electrode through a second via hole;
a first electrode layer electrically connected to the drain electrode or the source electrode through a third via hole;
a second electrode layer disposed on a surface of the second electrical conduction type semiconductor layer away from the base substrate;
a second insulating layer disposed on a surface of the first insulating layer away from the base substrate and covering the hydrogen barrier layer, the first electrode layer, the first electrical conduction type semiconductor layer, the intrinsic semiconductor layer, the second electrical conduction type semiconductor layer, and the second electrode layer which are exposed;
a planarization layer disposed on a surface of the second insulating layer away from the base substrate;
a third electrode layer disposed on a surface of the planarization layer away from the base substrate and electrically connected to the second electrode layer through a fourth via hole; and
a pixel defining layer disposed on a surface of the third electrode layer away from the base substrate,
wherein the first electrical conduction type semiconductor layer is disposed on a surface of the first electrode layer away from the base substrate;
wherein the intrinsic semiconductor layer is disposed on a surface of the first electrical conduction type semiconductor layer away from the base substrate;
wherein the second electrical conduction type semiconductor layer is disposed on a surface of the intrinsic semiconductor layer away from the base substrate.

13. The array substrate according to claim 10, further comprising:
a second electrode layer disposed on a surface of the second electrical conduction type semiconductor layer away from the base substrate;
a second insulating layer disposed on a surface of the interlayer insulating layer away from the base substrate and covering the source electrode, the drain electrode, the first electrical conduction type semiconductor layer, the intrinsic semiconductor layer, the second electrical conduction type semiconductor layer, and the second electrode layer which are exposed;
a planarization layer disposed on a surface of the second insulating layer away from the base substrate;
a third electrode layer disposed on a surface of the planarization layer away from the base substrate and electrically connected to the second electrode layer through a fourth via hole; and
a pixel defining layer disposed on a surface of the third electrode layer away from the base substrate,
wherein the first electrical conduction type semiconductor layer is disposed on a surface of the drain electrode or the source electrode away from the base substrate;
wherein the intrinsic semiconductor layer is disposed on a surface of the first electrical conduction type semiconductor layer away from the base substrate;
wherein the second electrical conduction type semiconductor layer is disposed on a surface of the intrinsic semiconductor layer away from the base substrate.

14. The array substrate according to claim 12, wherein the hydrogen barrier layer and the first electrode layer are disposed in a same layer.

15. (canceled)

16. A display panel, comprising the array substrate according to claim 1.

17. A method for manufacturing an array substrate, comprising:
forming a thin film transistor on a base substrate;
forming a first semiconductor layer on a side of the thin film transistor away from the base substrate;
forming an intermediate semiconductor layer on a surface of the first semiconductor layer away from the thin film transistor, the intermediate semiconductor layer covering the first semiconductor layer;
forming a second semiconductor layer on a surface of the intermediate semiconductor layer away from the thin film transistor, the second semiconductor layer covering the intermediate semiconductor layer; and
patterning the first semiconductor layer, the intermediate semiconductor layer, and the second semiconductor layer to form a first electrical conduction type semiconductor layer, an intrinsic semiconductor layer and a second electrical conduction type semiconductor layer, which constitute a PIN diode, on a surface of the thin film transistor away from the base substrate,
wherein a material from which the first electrical conduction type semiconductor layer is made comprises one or more of following materials: metal oxide, metal sulfide, metal selenide, metal nitride, metal phosphide, or metal arsenide.

18. The method according to claim 17, wherein the forming a thin film transistor on a base substrate comprises: forming an active layer, a gate insulating layer, a gate electrode, an interlayer insulating layer, a source electrode and a drain electrode on the base substrate sequentially,
wherein the first semiconductor layer is formed on a side of the drain electrode or the source electrode away from the active layer, and the first semiconductor layer covers the interlayer insulating layer which is exposed.

19. The method according to claim 18, wherein the forming an interlayer insulating layer comprises:
forming a plurality of stacked sub-interlayer insulating layers sequentially,
wherein two adjacent sub-interlayer insulating layers are formed in different powers and speeds.

20. The method according to claim 18, further comprising:
forming a light shielding layer on the base substrate;
forming a buffer layer on the base substrate, the buffer layer covering the light shielding layer,
wherein the active layer and the interlayer insulating layer are formed on a surface of the buffer layer away from the light shielding layer.

21. The method according to claim 17, wherein the first electrical conduction type semiconductor layer is manufactured in a hydrogen-free atmosphere.
